(19) United States
(12) Patent Application Publication
(10) Pub. No.: US 2021/0340663 A1
(43) Pub. Date: Nov. 4, 2021

(54) APPARATUS FOR PROCESSING A SUBSTRATE, SYSTEM FOR PROCESSING A SUBSTRATE, AND METHODS THEREFOR

(71) Applicants: Matthias HEYMANNS, Munster (DE); Jens GRÖLS, Alzenau (DE); Applied Materials, Inc., Santa Clara, CA (US)

(72) Inventors: Matthias HEYMANNS, Münster (DE); Jens GRÖLS, Alzenau (DE)

(21) Appl. No.: 16/329,123

(22) PCT Filed: Apr. 3, 2018
(86) PCT No.: PCT/EP2018/058472

§ 371 Date: Feb. 27, 2019

(51) Int. Cl. C23C 14/04; C23C 14/54; C23C 14/24; C23C 14/50; C23C 14/12

(52) U.S. Cl. CPC C23C 14/042; C23C 14/54; H01L 51/56; C23C 14/50; C23C 14/12; C23C 14/24

(57) ABSTRACT

An apparatus for processing a substrate in a vacuum chamber is described. The apparatus includes a first carrier transport system for transporting a first carrier along a first transport path in a first direction and a second carrier transport system for transporting a second carrier along a second transport path in the first direction. Further, the apparatus includes a measurement system for measuring a distance between the first carrier and the second carrier. The distance is perpendicular to the first direction.

### TECHNICAL FIELD

Embodiments of the present disclosure relate to apparatuses and systems for processing a substrate in a vacuum chamber employing two or more carriers, particularly a substrate carrier and a mask carrier. Further, embodiments of the present disclosure relate to methods of measuring a distance of a substrate carrier with respect to a mask carrier as well as to methods of aligning a substrate carrier with respect to a mask carrier. Embodiments of the present disclosure particularly relate to the deposition of a coating material on a substrate, wherein the substrate is aligned with respect to a mask before the deposition. Methods and apparatuses described herein may be used in the manufacture of organic light-emitting diode (OLED) devices.

### BACKGROUND

Techniques for layer deposition on a substrate include, for example, thermal evaporation, physical vapor deposition (PVD), and chemical vapor deposition (CVD). Coated substrates may be used in several applications and in several technical fields. For instance, coated substrates may be used in the field of organic light emitting diode (OLED) devices. OLEDs can be used for the manufacture of television screens, computer monitors, mobile phones, other hand-held devices and the like, for displaying information. An OLED device, such as an OLED display, may include one or more layers of an organic material situated between two electrodes that are all deposited on a substrate.

During the deposition of a coating material on a substrate, the substrate may be held by a substrate carrier, and a mask may be held by a mask carrier in front of the substrate. A material pattern, e.g. a plurality of pixels corresponding to an opening pattern of the mask, can be deposited on the substrate.

The functionality of an OLED device typically depends on a coating thickness of the organic material, which has to be within a predetermined range. For obtaining high-resolution OLED devices, technical challenges with respect to the deposition of evaporated materials need to be mastered. In particular, an accurate and smooth transportation of the substrate carriers and the mask carriers through a vacuum system is challenging. Further, a precise alignment of the substrate with respect to the mask is crucial for achieving high quality deposition results, e.g. for producing high-resolution OLED devices. Yet further, an efficient utilization of the coating material is beneficial, and idle times of the system are to be kept as short as possible.

In view of the above, there is a continuous demand for providing improved apparatuses, systems and methods for accurately and reliably positioning and/or aligning substrates and masks in a vacuum chamber.

### SUMMARY

In light of the above, an apparatus for processing a substrate in a vacuum chamber, a system for processing a substrate in a vacuum chamber, a method of measuring a distance between a first carrier and a second carrier, and a method of aligning a first carrier with a second carrier are provided. Further aspects, benefits, and features of the present disclosure are apparent from the claims, the description, and the accompanying drawings.

According to an aspect of the present disclosure, an apparatus for processing a substrate in a vacuum chamber is provided. The apparatus includes a first carrier transport system for transporting a first carrier along a first transport path in a first direction and a second carrier transport system for transporting a second carrier along a second transport path in the first direction. Further, the apparatus includes a measurement system for measuring a distance between the first carrier and the second carrier. The distance is perpendicular to the first direction.

According to another aspect of the present disclosure, an apparatus for processing a substrate in a vacuum chamber is provided. The apparatus includes a first carrier transport system for transporting a first carrier along a first transport path in a first direction and a second carrier transport system for transporting a second carrier along a second transport path in the first direction. Further, the apparatus includes a measurement system for measuring a distance between the substrate carried by the first carrier and a mask carried by the second carrier. The distance is perpendicular to the first direction. The measurement system includes a first measurement device for measuring a first distance between the substrate carried by the first carrier and the mask carried by the second carrier at a first position. The first measurement device is a first confocal sensor. Additionally, the measurement system includes a second measurement device for measuring a second distance between the substrate carried by the first carrier and the mask carried by the second carrier at a second position being different from the first position. The second measurement device is a second confocal sensor. Further, the measurement system includes a third measurement device for measuring a third distance between the substrate carried by the first carrier and the mask carried by the second carrier at a third position being different from the first position and the second position. The third measurement device is a third confocal sensor. The first measurement device, the second measurement device and the third measurement device are coupled to a linear actuator, the linear actuator providing a movement perpendicular to the first direction.

According to another aspect of the present disclosure, a system for processing a substrate is provided. The system includes an apparatus for processing a substrate in a vacuum chamber according to any of the embodiments described herein including a first carrier and a second carrier, the first carrier being a substrate carrier and the second carrier being a mask carrier. The first carrier includes through holes for receiving individual measurement devices of the measurement system.

According to a further aspect of the present disclosure, a method of measuring a distance between a first carrier and a second carrier is provided. The method includes providing the first carrier at a first position in a vacuum chamber; providing the second carrier at a second position in the vacuum chamber, such that the second carrier is substantially parallel to the first carrier. Additionally, the method includes introducing measurement devices of a measurement system into individual through holes of the first carrier. Further, the method includes fixing the position of the measurement devices relative to the first carrier and measuring the distance between the first carrier and the second carrier by employing the measurement devices.

According to yet another aspect of the present disclosure, a method of aligning a first carrier with a second carrier is provided. The method includes measuring at least three distances between first carrier and a second carrier at at least three different positions. Additionally, the method includes determining the differences between the at least three measured distances. Further, the method includes moving the first carrier relative to the second carrier such that the differences between the at least three measured distances are eliminated.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic view of an apparatus for processing a substrate according to embodiments described herein;

FIG. 2A shows a schematic view of an apparatus for processing a substrate according to embodiments described herein, the measurement system being in a first position;

FIG. 2B shows a schematic view of an apparatus for processing a substrate according to embodiments described herein, the measurement system being in a second position;

FIG. 3 shows a schematic sectional view of an apparatus for processing a substrate according to further embodiments described herein along the line A-A as indicated in FIG. 4;

FIG. 4 shows a schematic front view of an apparatus for processing a substrate according to further embodiments described herein, wherein the sectional view along the line A-A (see FIG. 3) and the sectional view along the line B-B (see FIG. 5) are indicated;

FIG. 5 shows a schematic sectional view of an apparatus for processing a substrate according to further embodiments described herein along line B-B indicated in FIG. 4;

FIG. 6 is a flow diagram illustrating a method of measuring a distance between a first carrier and a second carrier according to embodiments described herein; and

FIG. 7 is a flow diagram illustrating a method of aligning a first carrier with a second carrier according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

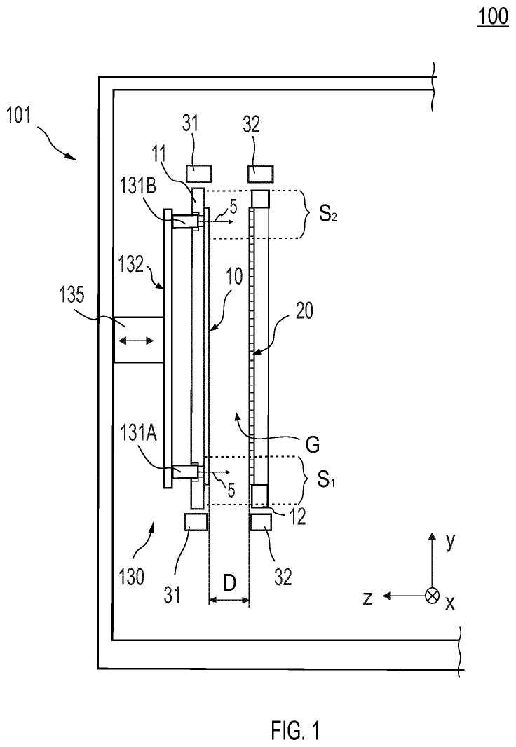

With exemplary reference to FIG. 1, an apparatus 100 for processing a substrate 10 in vacuum chamber 101 according to the present disclosure is described. According to embodiments which can be combined with any other embodiments described herein, the apparatus 100 includes a first carrier transport system 31 for transporting a first carrier 11 along a first transport path in a first direction X and a second carrier transport system 32 for transporting a second carrier 12 along a second transport path in the first direction X. The first carrier 11 can be a substrate carrier for carrying the substrate 10. The second carrier 12 can be a mask carrier for carrying a mask 20. Further, the apparatus includes a measurement system 130 for measuring a distance D between the first carrier 11 and the second carrier 12. In particular, as exemplarily shown in FIG. 1, the distance D between the first carrier 11 and the second carrier 12 is perpendicular to the first direction X. In FIG. 1, the first direction is perpendicular to the paper plane. For instance, the distance D between the first carrier 11 and the second carrier 12 may extend in the z-direction, as exemplarily shown in FIG. 1. More specifically, the distance D can be a gap provided between the first carrier and the second carrier. The gap may be understood as the space provided between opposing surfaces of the first carrier and the second carrier. Accordingly, the measurement system 130 can be configured for measuring a gap width between the first carrier and the second carrier.

Accordingly, embodiments of the apparatus as described herein are improved compared to conventional apparatuses. In particular, in contrast to conventional apparatuses in which the absolute positions of carriers are determined and controlled, embodiments as described herein beneficially provide for measuring a relative position of a first carrier, particularly of a substrate carried by the first carrier, with respect to a second carrier, particularly with respect to a mask carried by the second carrier. In other words, embodiments as described herein are configured for measuring a gap between a first carrier and a second carrier, particularly a gap between a substrate carried by the first carrier and a mask carried by the second carrier, such that advantageously contact of the first carrier with the second carrier, particularly contact of the substrate with the mask, can be avoided. Further, measuring a distance between a first carrier and the second carrier, particularly a distance between a substrate carried by the first carrier and a mask carried by the second carrier, can be beneficial for improving the performance of an alignment of the first carrier and the second carrier, particularly an alignment of a substrate carried by the first carrier and a mask carried by the second carrier. For instance, by providing an apparatus with which information about a distance between a first carrier and a second carrier, particularly a distance between a substrate carried by the first carrier and a mask carried by the second carrier, can be obtained, i.e. a gap between the first carrier and the second carrier, particularly a gap between a substrate carried by the first carrier and a mask carried by the second carrier, beneficially it is possible to determine whether the first carrier, particularly the substrate carried by the first carrier, and the second carrier, particularly the mask carried by the second carrier, are parallel to each other or not. Accordingly, embodiments of the present disclosure beneficially provide for measuring a parallelism of the first carrier and the second carrier, particularly parallelism of a substrate carried by the first carrier and a mask carried by the second carrier, such that if deviation from parallelism is detected, the relative position of the first carrier and the second carrier, particularly the relative position the substrate and the mask, can be adjusted in order to establish parallelism.

Before various further embodiments of the present disclosure are described in more detail, some aspects with respect to some terms used herein are explained.

In the present disclosure, an “apparatus for processing a substrate in a vacuum chamber” can be understood as an apparatus which is configured for processing, particularly for coating, a substrate as described herein under vacuum conditions. In particular, embodiments described herein can be utilized for depositing one or more materials, e.g. by a vapor deposition process, on large area substrates, e.g., for OLED display manufacturing. Accordingly, embodiments of the apparatus as described herein can be configured for material evaporation, e.g. an organic material, for the manufacture of OLED devices. As an example, the deposition source can be an evaporation source, particularly an evaporation source for depositing one or more organic materials on a substrate to form a layer of an OLED device.

A “substrate” according to the present disclosure may be a large area substrate, e.g. having a surface area of 0.5 m² or more, particularly 1 m² or more. For instance, a large area substrate can be GEN 4.5, which corresponds to a surface area of about 0.67 m² (0.73×0.92 m), GEN 5, which corresponds to a surface area of about 1.4 m² (1.1 m×1.3 m), GEN 7.5, which corresponds to a surface area of about 4.29 m² (1.95 m×2.2 m), GEN 8.5, which corresponds to a surface area of about 5.7 m² (2.2 m×2.5 m), or even GEN 10, which corresponds to a surface area of about 8.7 m² (2.85 m×3.05 m). Even larger generations such as GEN 11 and GEN 12 and corresponding surface areas can similarly be implemented. Half sizes of the GEN generations may also be provided in OLED display manufacturing.

Accordingly, a substrate as described herein may be made of any material suitable for material deposition. In particular, the substrate may be transparent. For instance, the substrate may be made of a material selected from the group consisting of glass (for instance soda-lime glass, borosilicate glass, and the like), metal, polymer, ceramic, compound materials, carbon fiber materials or any other material or combination of materials which can be coated by a deposition process.

According to some embodiments, which can be combined with other embodiments described herein, the substrate thickness can be from 0.1 to 1.8 mm. The substrate thickness can be about 0.9 mm or below, such as 0.5 mm. The term “substrate” as used herein may particularly embrace substantially inflexible substrates, e.g., a wafer, slices of transparent crystal such as sapphire or the like, or a glass plate. However, the present disclosure is not limited thereto, and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.9 mm or below, such as 0.5 mm or below, wherein the flexibility of the substantially inflexible substrate is small in comparison to the flexible substrates.

In the present disclosure, a “vacuum chamber” can be understood as a chamber configured for vacuum deposition. The term “vacuum”, as used herein, can be understood in the sense of a technical vacuum having a vacuum pressure of less than, for example, 10 mbar. Typically, the pressure in a vacuum chamber as described herein may be between 10⁻⁵ mbar and about 10⁻⁸ mbar, more typically between 10⁻⁵ mbar and 10⁻⁷ mbar, and even more typically between about 10⁻⁶ mbar and about 10⁻⁷ mbar. According to some embodiments, the pressure in the vacuum chamber may be considered to be either the partial pressure of the evaporated material within the vacuum chamber or the total pressure (which may approximately be the same when only the evaporated material is present as a component to be deposited in the vacuum chamber). In some embodiments, the total pressure in the vacuum chamber may range from about 10⁻⁴ mbar to about 10⁻⁷ mbar, especially in the case that a second component besides the evaporated material is present in the vacuum chamber (such as a gas or the like).

In the present disclosure, a “first carrier” can be understood as a carrier which is configured for holding a substrate 10, as schematically shown in FIG. 1. Accordingly, the first carrier can be a substrate carrier. In particular, a substrate carrier can be understood as a carrier device configured for carrying a substrate, e.g. along a substrate transportation path in a vacuum chamber. For instance, the substrate carrier may hold the substrate during the deposition of a coating material on the substrate. Accordingly, a “first carrier” as described herein can be understood as a first carrier including a substrate. In other words, the term “first carrier” may refer to a first carrier carrying a substrate.

For example, the substrate may be held at a holding surface of the first carrier during the transport through a vacuum chamber, during positioning of the substrate in the vacuum chamber, e.g. with respect to a mask, and/or during the deposition of a coating material on the substrate. In particular, the substrate may be held by the first carrier by a chucking device, e.g. by an electrostatic chuck or by a magnetic chuck. The chucking device may be integrated in the first carrier. In some embodiments, the substrate may be held by the substrate carrier in a non-horizontal orientation, particularly in an essentially vertical orientation, e.g. during transport and/or deposition.

An “essentially vertical orientation” as used herein may be understood as an orientation with a deviation of 10° or less, particularly 5° or less from a vertical orientation, i.e. from the gravity vector. For example, an angle between a main surface of a substrate (or mask) and the gravity vector may be between +10° and −10°, particularly between 0° and −5°. In some embodiments, the orientation of the substrate (or mask) may not be exactly vertical during transport and/or during deposition, but slightly inclined with respect to the vertical axis, e.g. by an inclination angle between 0° and −5°, particularly between −1° and −5°. A negative angle refers to an orientation of the substrate (or mask) wherein the substrate (or mask) is inclined downward. A deviation of the substrate orientation from the gravity vector during deposition may be beneficial and might result in a more stable deposition process, or a facing down orientation might be suitable for reducing particles on the substrate during deposition. However, also an exactly vertical orientation)(+1-1° during transport and/or during deposition is possible. In other embodiments, the substrates and masks may be transported in a non-vertical orientation, and/or the substrates may be coated in a non-vertical orientation, e.g. an essentially horizontal orientation.

A “second carrier” as described herein can be understood as a carrier which is configured for holding mask 20, as schematically shown in FIG. 1. Accordingly, the second carrier can be a mask carrier. In particular, a “mask carrier” can be understood as a carrier device configured for carrying a mask for the transport of the mask along a mask transport path in the vacuum chamber. For instance, the mask carrier may carry the mask during transport, during alignment with respect to a substrate and/or during deposition on the substrate. Accordingly, a “second carrier” as described herein can be understood as a second carrier including a mask. In other words, the term “second carrier” may refer to a second carrier carrying a mask.

In some embodiments, the mask may be held by the mask carrier in a non-horizontal orientation, particularly in an essentially vertical orientation during transport and/or deposition. In particular, the mask may be held at the mask carrier by a chucking device, e.g. a mechanic chuck such as a clamp, an electrostatic chuck or a magnetic chuck. Other types of chucking devices may be used which may be connected to or integrated in the mask carrier.

For instance, a mask as described herein may be an edge exclusion mask or a shadow mask. An edge exclusion mask is a mask which is configured for masking one or more edge regions of the substrate, such that no material is deposited on the one or more edge regions during the coating of the substrate. A shadow mask is a mask configured for masking a plurality of features which are to be deposited on the substrate. For instance, the shadow mask can include a plurality of small openings, e.g. a grid of small openings.

In the present disclosure, a “carrier transport system” can be understood as a system configured for transporting a carrier along a transport path. The transport path can be understood as the path or trajectory along which the carrier is moved during transportation. For instance, with exemplary reference to FIG. 1, it is to be understood that the first carrier transport system 31 is configured for transporting the first carrier 11 along a first transport path in a first direction X and that the second carrier transport system 32 is configured for transporting a second carrier 12 along a second transport path in the first direction X. In FIG. 1, the first direction X is essentially perpendicular to the paper plane.

According to some embodiments which can be combined with other embodiments described herein, the first carrier transport system 31 may be configured for a contactless transport of the first carrier 11 in the vacuum chamber 101. For example, the first carrier transport system 31 may hold and transport the first carrier 11 by magnetic forces. In particular, the first carrier transport system 31 may include a magnetic levitation system. Similarly, the second carrier transport system 32 may be configured for a contactless transport of the second carrier 12 in the vacuum chamber 101. For example, the second carrier transport system 32 may hold and transport the second carrier 12 by magnetic forces. In particular, the second carrier transport system 32 may include a magnetic levitation system

In the present disclosure, a “measurement system” can be understood as a system configured for conducting a measurement, particularly for measuring a distance, e.g. a distance between the first carrier and the second carrier as described herein. In particular, the measurement system can be a system which is configured for measuring a distance between two objects, e.g. a first carrier and a second carrier, by employing an optical measurement technique. For instance, the measurement system can include one, two, or more measurement devices, e.g. confocal sensors, for conducting a distance measurement. As exemplarily indicated by the dotted arrows 5 in FIG. 1, typically the measurement devices, particularly the confocal sensors, are configured for emitting radiation, particularly light.

As described herein, a “first carrier” can be understood as a “first carrier including a substrate and the “second carrier” can be understood as a “second carrier” including a mask. In other words, a “first carrier” may refer to a first carrier carrying a substrate and a “second carrier” may refer to a second carrier carrying a mask.

Accordingly, it is to be understood that the expression “distance between the first carrier and the second carrier” may refer to a distance between a substrate carried by the first carrier and a mask carried by the second carrier. Alternatively, the expression “distance between the first carrier and the second carrier” may refer to a distance between a substrate carried by the first carrier and a body of the second carrier, e.g. a frame of the second carrier. According to another alternative, the expression “distance between the first carrier and the second carrier” may refer to a distance between a body of the first carrier, e.g. a frame of the first carrier, and a body of the second carrier, e.g. a frame of the second carrier. The above given understanding of the expression “distance between the first carrier and the second carrier” may also apply to the first distance D1, the second distance D2, the third distance D3 and fourth distance D4 as described herein.

With exemplary reference to FIG. 1, according to some embodiments which can be combined with other embodiments described herein, the measurement system 130 includes a first measurement device 131A and a second measurement device 131B. In particular, the first measurement device 131A and the second measurement device 131B are spaced apart. More specifically, the first measurement device 131A can be arranged and configured for measuring a distance between the first carrier 11 and the second carrier 12 on a first side S1 of the gap G.

The second measurement device 131B can be arranged and configured for measuring a distance between the first carrier and the second carrier on a second side S2 of the gap G. The second side S2 of the gap G is opposite the first side S1 of the gap G. Accordingly, beneficially distance measurements at different locations can be carried out which allows to determine whether the first carrier and the second carrier are parallel to each other or not.

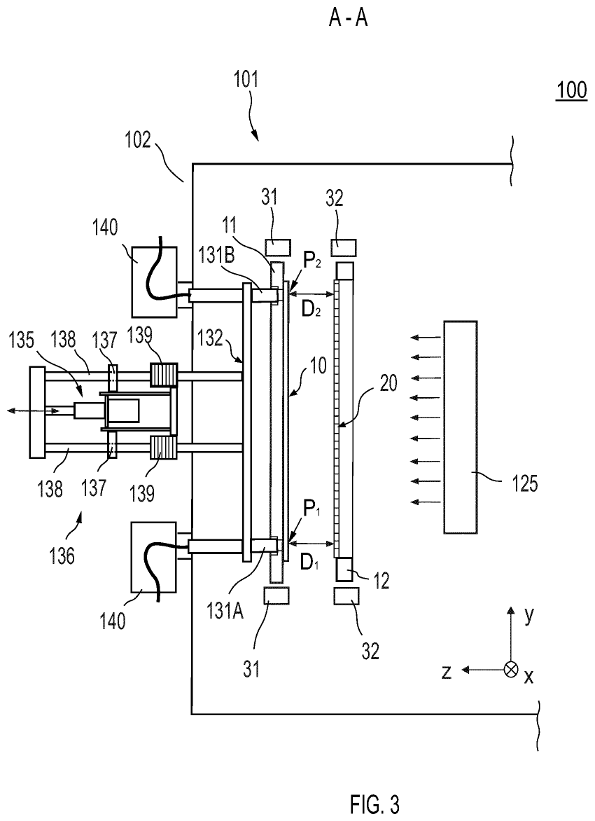

In other words, as exemplarily shown in FIG. 3, according to embodiments which can be combined with other embodiments described herein, the measurement system 130 includes a first measurement device 131A for measuring a first distance D1 between the first carrier 11 and the second carrier 12 at a first position P1. Additionally, the measurement system 130 includes a second measurement device 131B for measuring a second distance D2 between the first carrier 11 and the second carrier 12 at a second position P2 being different from the first position P1. Accordingly, it is to be understood that in the case that the first distance D1 is equal to the second distance D2, the first carrier and the second carrier are parallel to each other along the line connecting the first position P1 and the second position P2.

According to some embodiments which can be combined with other embodiments described herein, the first measurement device 131A is a first optical measurement device, particularly a first confocal sensor. Accordingly, the second measurement device 131B can be a second optical measurement device, particularly a second confocal sensor. An “optical measurement device” can be understood as a device which is configured for measuring a distance by employing an optical measurement technique. A “confocal sensor” can be understood as a sensor which is configured for measuring a displacement by employing light. For example, typically the confocal sensor is based on the measuring principle that separates emitted light into different colors and then uses a detector to identify the reflected color signal. Accordingly, beneficially the distance between the first carrier and the second carrier can be measured in a contactless way. Further, employing confocal sensors has the advantage that displacement measurements can be carried out at very high accuracy, e.g. in the micro meter range or even in the sub-micro meter range.

With exemplary reference to FIG. 1, according to some embodiments which can be combined with other embodiments described herein, the first measurement device 131A and the second measurement device 131B are rigidly connected by a holding arrangement 132. A “holding arrangement” can be understood as a mechanical structure configured for holding a first measurement device and a second measurement device as described herein. Accordingly, beneficially the position of the first measurement device and the position of the second measurement device can be fixed relative to each other, which can be advantageous for determining the parallelism of the first carrier and the second carrier.

As exemplarily shown in FIG. 1, according to some embodiments which can be combined with other embodiments described herein, the measurement system 130 includes a linear actuator 135 for moving the first measurement device 131A and the second measurement device 131B perpendicular to the first direction X, e.g. the z-direction shown in FIG. 1. A “linear actuator” can be understood as an actuator configured for performing a translational movement.

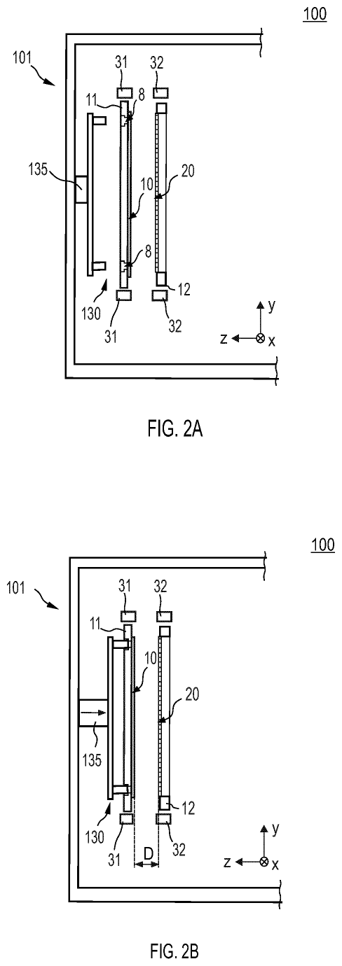

FIG. 2A shows a schematic view of the apparatus 100 in which the measurement system 130 is in a first position and FIG. 2B shows the apparatus in which the measurement system is in a second position. Accordingly, as can be understood from FIGS. 2A and 2B, the linear actuator 135 can be employed for moving the measurement devices from a first position to a second position and vice versa. For instance, the first position can be a transfer position and the second position can be a measurement position. The transfer position (FIG. 2A) can be understood as a position which allows for moving the first carrier relative to measurement devices and relative to the second carrier in the first direction X. The measurement position (FIG. 2B) can be understood as the position of the measurement devices in which displacement measurement for measuring a distance between the first carrier and the second carrier is carried out. In particular, as exemplarily shown in FIGS. 1 and 2B, in the measurement position the first measurement device and the second measurement device are introduced into respective receptions, particularly through holes, of the first carrier. As exemplarily shown in FIG. 2A, the receptions 8 can be configured for providing a mechanical stop for the respective measurement devices.

With exemplary reference to FIG. 3, according to some embodiments which can be combined with other embodiments described herein, the measurement system 130 comprises a guiding arrangement 136 for guiding a movement of the first measurement device 131A and the second measurement device 131B perpendicular to the first direction X. In particular, as exemplarily shown in FIG. 3, the guiding arrangement 136 can be arranged outside the vacuum chamber 101. In particular, the guiding arrangement may include a guiding element 137 and a sliding element 138. The sliding element 138 can be configured to be guided by the guiding element 137. Typically, the sliding element 138 is movable relative to the guiding element, e.g. by employing a linear actuator. Accordingly, the sliding element 138 can be coupled to the linear actuator 135, as exemplarily shown in FIG. 3.

According to some embodiments which can be combined with other embodiments described herein, the sliding element 138 can extend through a wall 102 of the vacuum chamber 101. In particular, as exemplarily shown in FIG. 3, one part of the sliding element may partially be arranged outside the vacuum chamber and the other part of the sliding element may be arranged inside the vacuum chamber. Further, the sliding element 138 can be coupled to the holding arrangement 132, as shown in FIG. 3. The holding arrangement 132 can be arranged inside the vacuum chamber 101. According to an exemplary implementation, membrane bellows 139 may be provided for vacuum sealing. Further, as exemplarily shown in FIG. 3, vacuum housings 140 may be provided. In particular, the vacuum housings may be attached to an outside wall of the vacuum chamber 101, e.g. wall 102 shown in FIG. 3. A vacuum housing can be understood as a compartment in which welcome conditions can be provided and maintained. The vacuum housings 140 are typically configured for receiving a cable connected to the respective measurement device.

As exemplarily shown in FIG. 3, according to some embodiments which can be combined with other embodiments described herein, a deposition source 125 is provided in the vacuum chamber 101. The deposition source 125 is configured for depositing a coating material on the substrate 10 that is held by the first carrier 11.

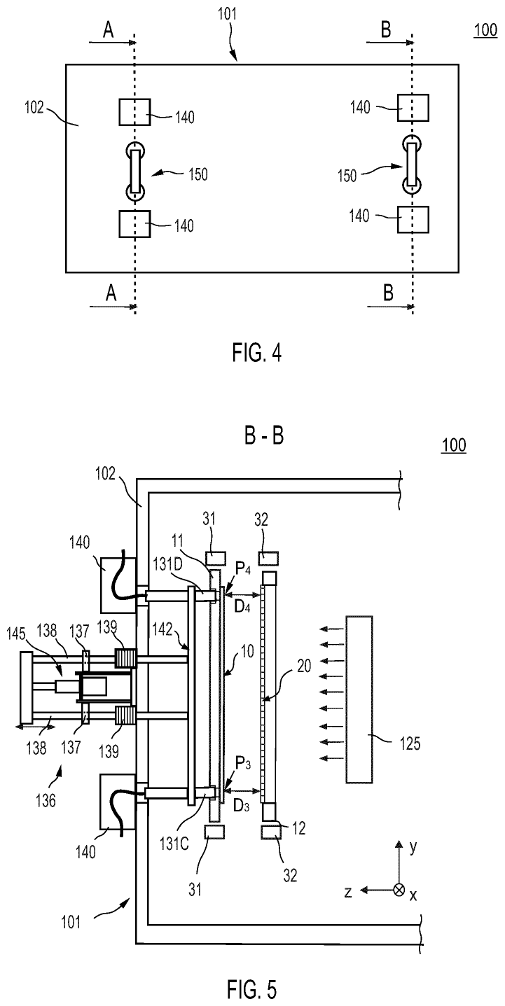

FIG. 4 shows a schematic front view of the apparatus 100. In particular, FIG. 4 shows a substantially vertical outer wall of the vacuum chamber 101. As can be seen from FIG. 4, more than two vacuum housings 140 can be attached to the wall 102 of the vacuum chamber, e.g. three, four or more vacuum housings. Accordingly, it is to be understood that the apparatus as described herein may include three, four or more measurement devices.

In particular, as exemplarily shown in FIG. 5, according to some embodiments which can be combined with other embodiments described herein, the measurement system 130 includes a third measurement device 131C for measuring a third distance D3 between the first carrier 11 and the second carrier 12 at a third position P3 being different from the first position P1 and the second position P2. FIG. 5 shows a sectional view along line B-B depicted in FIG. 4 and FIG. 3 shows a sectional view along line A-A depicted in FIG. 4. Accordingly, beneficially three distances or displacements between the first carrier and the second carrier can be measured, which has the advantage that the plane parallelism of the first carrier and the second can be determined.

Further, with exemplarily reference to FIG. 5, according to some embodiments which can be combined with other embodiments described herein, the measurement system 130 includes a fourth measurement device 131D for measuring a fourth distance D4 between the first carrier 11 and the second carrier 12 at a fourth position P4 being different from the first position P1, from the second position P2 and from the third position P3. Accordingly, beneficially the plane parallelism of the first carrier and the second carrier can be measured with increased accuracy compared to a configuration in which three or less measurement device are used.

The third measurement device 131C can be third optical measurement device, particularly a third confocal sensor. Accordingly, the fourth measurement device 131D can be a fourth optical measurement device, particularly a fourth confocal sensor.

According to some embodiments which can be combined with other embodiments described herein, the third measurement device 131C and the fourth measurement device 131D are rigidly connected by a further holding arrangement 142. In particular, the further holding arrangement 142 can be connected to a further linear actuator 145 for providing a movement perpendicular to the first direction X. As shown in FIG. 5, a sliding element 138, a guiding element 137, and membrane bellows 139 may be provided in an analogous way as exemplarily described with reference to FIG. 3.

According to some embodiments which can be combined with other embodiments described herein, the measurement system 150 comprises a mounting assembly for connecting the measurement system to a wall of the vacuum chamber, as schematically shown in FIG. 4.

According to a particular example, which can be combined with other embodiments described herein, an apparatus 100 for processing a substrate in a vacuum chamber 101 includes a first carrier transport system 31 configured to transport a first carrier 11 along a first transport path in a first direction X and a second carrier transport system 32 configured to transport a second carrier 12 along a second transport path in the first direction X. Additionally, the apparatus includes a measurement system 130 configured for measuring a distance D between the first carrier 11 and the second carrier 12, the distance D being perpendicular to the first direction X. The measurement system 130 includes a first measurement device 131A for measuring a first distance D1 between the first carrier 11 and the second carrier 12 at a first position P1. The first measurement device 131A typically is a first confocal sensor. Additionally, the measurement system 130 includes a second measurement device 131B for measuring a second distance D2 between the first carrier 11 and the second carrier 12 at a second position P2 being different from the first position P1. The second measurement device 131B typically is a second confocal sensor. Further, the measurement system 130 includes a third measurement device 131C for measuring a third distance D3 between the first carrier 11 and the second carrier 12 at a third position P3 being different from the first position P1 and the second position P2. The third measurement device typically is a third confocal sensor. The first measurement device 131A, the second measurement device 131B and the third measurement device 131C are coupled to a linear actuator. The linear actuator is configured for providing a movement perpendicular to the first direction X.

According to an aspect of the present disclosure, a system for processing a substrate is described in the following. The system for processing a substrate includes the apparatus for processing a substrate according to any of the embodiments described herein. Further, the system includes a first carrier 11 and a second carrier 12. Typically, the first carrier 11 is a substrate carrier and the second carrier is a mask carrier. In particular, the first carrier includes through holes for receiving individual measurement devices of the measurement system 130. For instance, the through holes can be configured as receptions 8 as exemplarily described with reference to FIG. 2A. The receptions can include a mechanical stop for the respective measurements devices introduced into the receptions when the measurement system is in a measurement position. It is to be understood that the measurement system may be implemented according to any embodiments described herein.

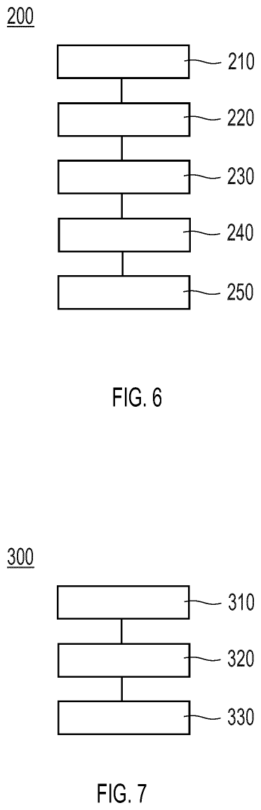

With exemplary reference to the flowchart shown in FIG. 6, embodiments of a method 200 of measuring a distance between a first carrier 11 and a second carrier 12 according to the present disclosure are described. According to some embodiments which can be combined with other embodiments described herein, the method includes providing the first carrier at a first position in a vacuum chamber (block 210) and providing the second carrier at a second position in the vacuum chamber (block 220). Typically, the first carrier and the second carrier are provided to be substantially parallel to each other. Additionally, the method includes introducing measurement devices (block 230) of a measurement system into individual through holes of the first carrier, e.g. receptions 8 as described herein. Further, the method includes fixing the position of the measurement devices relative to the first carrier (block 240). For instance, the position of the measurement devices can be fixed by employing the stops of the receptions as described with reference to FIG. 2A. Additionally, the method includes measuring the distance between the first carrier 11 and the second carrier 12 (block 250) by the employing the measurement devices.

According to some embodiments which can be combined with other embodiments described herein, measuring the distance between the first carrier and the second carrier includes measuring the distance at at least three different positions, particularly at at least three corners of the first carrier. For example, the at least three different positions can be three positions selected from the group consisting of the first position P1, the second position P2, the third position P3 and the fourth position P4, as described herein.

With exemplary reference to the flowchart shown in FIG. 7, embodiments of a method 300 of aligning a first carrier with a second carrier according to the present disclosure are described. The method includes measuring (block 310) at least three distances between a first carrier and a second carrier at at least three different positions. Additionally, the method includes determining (block 320) the differences between the at least three measured distances. Further, the method includes moving (block 330) the first carrier relative to the second carrier such that the differences between the at least three measured distances are eliminated.

For example, moving the first carrier relative to the second carrier may include employing an alignment system which is configured to accurately position the first carrier 11 relative to the second carrier. Accordingly, the apparatus as described herein may include an alignment system provided in the vacuum chamber. Further, it is to be understood that the measurement system as described herein can be connected with the alignment system, for instance by a controller. Accordingly, the measurement data obtained by the measurement system can be sent to the controller which can be configured to send a control signal to the alignment system, if the measurement data shows that the position of the first carrier relative to the second carrier is not at a pre-defined position. Accordingly, beneficially a distance between the first carrier and the second carrier can be monitored and controlled, e.g. for ensuring that the first carrier is parallel to the second carrier.

According to embodiments described herein, the method of measuring a distance between the first carrier and the second carrier as well as the method of aligning the first carrier with the second carrier can be conducted using computer programs, software, computer software products and the interrelated controllers, which can have a CPU, a memory, a user interface, and input and output devices being in communication with the corresponding components of the apparatus.

In view of the embodiments described herein, it is to be understood that the embodiments of the apparatus for processing a substrate evaporator, the system for processing a substrate and the methods therefor are improved with respect to the state of the art. In particular, embodiments of the present disclosure have the advantage that in contrast to the state of the art in which the absolute positions of carriers are determined and controlled, embodiments as described herein beneficially provide for measuring a relative position of a first carrier, particularly of a substrate carried by the first carrier, with respect to a second carrier, particularly with respect to a mask carried by the second carrier. In other words, embodiments as described herein are configured for measuring a gap between a first carrier and a second carrier particularly a gap between a substrate carried by the first carrier and a mask carried by the second carrier, such that advantageously contact of the first carrier with the second carrier, particularly contact of the substrate with the mask, can be avoided. Further, embodiments of the present disclosure provide for improving the performance of an alignment of the first carrier and the second carrier, particularly an alignment of a substrate carried by the first carrier and a mask carried by the second carrier, since the distance or gap between the first carrier and the second carrier, particularly the distance or gap between substrate carried by the first carrier and the mask carried by the second carrier, can continuously be monitored and controlled. Accordingly, embodiments of the present disclosure beneficially provide for controlling parallelism of the first carrier and the second carrier, particularly parallelism of a substrate carried by the first carrier and a mask carried by the second carrier, such that if deviation from parallelism is detected, the relative position of the first carrier and the second carrier, particularly the relative position the substrate and the mask, can be adjusted in order to establish parallelism, e.g. by using an alignment system. For instance, the alignment system may include actuators, particularly linear actuators, arranged and configured for performing the alignment of the substrate carried by the first carrier and the second carrier, particularly a mask carried by the second carrier. For example, the actuators can be piezo actuators.

While the foregoing is directed to embodiments of the disclosure, other and further embodiments of the disclosure may be devised without departing from the basic scope thereof, and the scope thereof is determined by the claims that follow.

1. An apparatus for processing a substrate in a vacuum chamber comprising:
a first carrier transport system for transporting a first carrier along a first transport path in a first direction;
a second carrier transport system for transporting a second carrier along a second transport path in the first direction; and
a measurement system for measuring a distance between the first carrier and the second carrier, the distance being perpendicular to the first direction.

2. The apparatus of claim 1, wherein the measurement system comprises a first measurement device for measuring a first distance between the first carrier and the second carrier at a first position and a second measurement device for measuring a second distance between the first carrier and the second carrier at a second position being different from the first position.

3. The apparatus of claim 2, wherein the first measurement device is a first optical measurement device and wherein the second measurement device is a second optical measurement device.

4. The apparatus of claim 2, wherein the first measurement device and the second measurement device are rigidly connected by a holding arrangement.

5. The apparatus of claim 2, wherein the measurement system comprises a linear actuator for moving the first measurement device and the second measurement device perpendicular to the first direction.

6. The apparatus of claim 2, wherein the measurement system comprises a guiding arrangement for guiding a movement of the first measurement device and the second measurement device perpendicular to the first direction.

7. The apparatus of claim 2, wherein the measurement system comprises a third measurement device for measuring a third distance between the first carrier and the second carrier at a third position being different from the first position and the second position.

8. The apparatus of claim 2, wherein the measurement system comprises a fourth measurement device for measuring a fourth distance between the first carrier and the second carrier at a fourth position being different from the first position, from the second position and from the third position.

9. The apparatus (100) of claim 2, wherein the measurement system comprises a third measurement device for measuring a third distance between the first carrier and the second carrier at a third position being different from the first position and the second position, wherein the measurement system comprises a fourth measurement device for measuring a fourth distance between the first carrier and the second carrier at a fourth position being different from the first position, from the second position and from the third position, and wherein the third measurement device and the fourth measurement device are rigidly connected by a further holding arrangement, particularity the further holding arrangement being connected to a further linear actuator for providing a movement perpendicular to the first direction.

10. The apparatus of claim 1, wherein the measurement system comprises a mounting assembly for connecting the measurement system to a wall of the vacuum chamber.

11. An apparatus for processing a substrate in a vacuum chamber comprising:
a first carrier transport system for transporting a first carrier along a first transport path in a first direction;
a second carrier transport system for transporting a second carrier along a second transport path in the first direction; and
a measurement system for measuring a distance between the substrate carried by the first carrier and a mask carried by the second carrier, the distance being perpendicular to the first direction, the measurement system comprising:
a first measurement device for measuring a first distance between the substrate carried by the first carrier and the mask carried by the second carrier at a first position, the first measurement device being a first confocal sensor;
a second measurement device for measuring a second distance between the substrate carried by the first carrier and the mask carried by the second carrier at a second position being different from the first position, the second measurement device being a second confocal sensor; and
a third measurement device for measuring a third distance between the substrate carried by the first carrier and the mask carried by the second carrier at a third position being different from the first position and the second position, the third measurement device being a third confocal sensor, wherein the first measurement device, the second measurement device and the third measurement device are coupled to a linear actuator, the linear actuator being configured for providing a movement perpendicular to the first direction.

12. A system for processing a substrate, comprising an apparatus for processing a substrate in a vacuum chamber, the apparatus (100) comprising:
a first carrier transport system for transporting a first carrier along a first transport path in a first direction;
a second carrier transport system for transporting a second carrier along a second transport path in the first direction; and
a measurement system for measuring a distance between the first carrier and the second carrier, the distance being perpendicular to the first direction, the system further comprising a first carrier and a second carrier, the first carrier being a substrate carrier and the second carrier being a mask carrier, wherein the first carrier comprises through holes for receiving individual measurement devices of the measurement system.

13. A method of measuring a distance between a first carrier and a second carrier, the method comprising:
providing the first carrier at a first position in a vacuum chamber;
providing the second carrier at a second position in the vacuum chamber, such that the second carrier is substantially parallel to the first carrier;
introducing measurement devices of a measurement system into individual through holes of the first carrier;
fixing the position of the measurement devices relative to the first carrier; and
measuring the distance between the first carrier and the second carrier by employing the measurement devices.

14. The method of claim 13, wherein measuring the distance between the first carrier and the second carrier includes measuring the distance at least three different positions.

15. Method of aligning a first carrier with a second carrier, the method comprising:
measuring at least three distances between first carrier and the second carrier at at least three different positions, determining the differences between the at least three measured distances, and moving the first carrier relative to the second carrier such that the differences between the at least three measured distances are eliminated.

16. The apparatus of claim 2, wherein the first measurement device is a first confocal sensor and wherein the second measurement device is a second confocal sensor.

17. The apparatus of claim 4, wherein the measurement system comprises a linear actuator for moving the first measurement device and the second measurement device perpendicular to the first direction.

18. The apparatus of claim 4, wherein the measurement system comprises a guiding arrangement for guiding a movement of the first measurement device and the second measurement device perpendicular to the first direction.

19. The apparatus of claim 5, wherein the measurement system comprises a guiding arrangement for guiding a movement of the first measurement device and the second measurement device perpendicular to the first direction.

20. The method of claim 17, wherein measuring the distance between the first carrier and the second carrier includes measuring the distance at at least three corners of the first carrier.
